(19) United States
(12) Patent Application Publication
(10) Pub. No.: US 2013/0286595 A1
(43) Pub. Date: Oct. 31, 2013

(54) THERMAL MANAGEMENT FLOORPLAN FOR A MULTI-TIER STACKED IC PACKAGE

(71) Applicant: QUALCOMM INCORPORATED, San Diego, CA (US)

(72) Inventors: Durodami J. Lisk, San Diego, CA (US); Victor A. Chiriac, San Diego, CA (US); Ratibor Rakojcic, San Diego, CA (US)

(73) Assignee: QUALCOMM INCORPORATED, San Diego, CA (US)

(21) Appl. No.: 13/681,409

(22) Filed: Nov. 19, 2012

Related U.S. Application Data
(60) Provisional application No. 61/639,286, filed on Apr. 27, 2012.

(51) Int. Cl. H05K 13/00; H05K 7/20

(52) U.S. Cl. CPC H05K 13/00; H05K 7/2039
USPC 361/719; 29/829; 361/718

(57) ABSTRACT

A first tier die is provided having a thermal management floorplan with a heat region having an area for thermal coupling to a heat sink, a second tier die is provided, shaped and dimensioned to be stackable into a multi-tier stack with the first tier die and, when stacked in the multi-tier stack, to not substantially overlap the heat region. A heat sink is provided, and a thermal coupling element, the heat sink, a stack having the first tier die and the second tier die, and the heat sink are arranged to form the multi-tier stacked integrated circuit. In the arrangement, the thermal coupling element is located to form a thermal path from the heat region of the first tier die to the heat sink.

### RELATED APPLICATIONS

The present application claims the benefit of U.S. Provisional Patent Application No. 61/639,286 filed on Apr. 27, 2012 in the names of Durodami Lisk et al., the disclosures of which is expressly incorporated by reference herein in entirety.

### FIELD OF DISCLOSURE

The present application relates to packaging of integrated circuit chips and, more particularly to management and dissipation of heat generated by stacked chips.

### BACKGROUND

High-density packaging of integrated circuit (IC) chips or dies can include a stacked or multi-tiered arrangement. Such stacked arrangements can be formed of a lower or first tier IC die on a package substrate and a second tier IC die on the first tier IC die. The second tier IC die can be the top tier, or another, third tier IC die can overlay the second tier, and so forth.

Due to contributions from a plurality of mechanisms, heat can be a substantial issue in multi-tiered IC die packaging. For example, in conventional multi-tiered IC die stacks, IC dies stacked above a first tier IC die can prevent that first tier IC die from having direct thermal contact with an overlaying heat spreader. The bottom tier IC die does have direct contact with the package substrate. However, certain conventional substrate materials are selected to meet certain requirements, e.g., a specific co-efficient of thermal expansion or dielectric property, particular to the functions of a substrate. Because of such materials, the substrate may have a high thermal resistance.

Conventional heat control techniques may be used, such as lowering of clock rates or adding of design constraints, for example, constraints in the distribution and location of high heat generating circuits. In addition, large surface area heat sinks can be used to partially compensate for high thermal resistance paths to IC dies in the multi-tiered stack. However, these conventional heat control techniques can have various costs.

### SUMMARY

Exemplary embodiments include, among other features, improved thermal coupling to heat regions in lower, upper or middle tier IC dies in a multi-tier IC package.

In accordance with various exemplary embodiments, methods of fabricating a multi-tier stacked integrated circuit may include providing a first tier die having a thermal management floorplan having a heat region having an area for a thermal coupling to a heat sink, and providing a second tier die, shaped and dimensioned to be stackable into a multi-tier stack. In an aspect, the first tier die may be configured such that when stacked in the multi-tier stack, it does not substantially overlap the heat region of the first tier die. Methods according to various exemplary embodiments may further include providing a heat sink, and arranging a thermal coupling element, the heat sink and a stack having the first tier die and the second tier die, to form the multi-tier stacked integrated circuit. In an aspect, the arranging includes locating the thermal coupling element to provide a thermal path from the heat region of the first tier die to the heat sink.

In an aspect, the thermal management floorplan of the first tier die may comprise a heat-sensitive component located away from the heat region. In another aspect, the first tier die may further comprise a heat-source component located in the heat region, the heat-source component designated to be thermally managed by the thermal path from the heat region to the heat sink provided by the thermal coupling element.

In an aspect, arranging the thermal coupling element, the multi-tier stack of the first tier die and the second tier die, and the heat sink forms the multi-tier stacked integrated circuit with the thermal coupling element contacting a surface of the heat sink and a surface of the heat region of the first tier die.

In an aspect, providing a second tier die configured to not substantially overlap the heat region further comprises configuring the second tier die to have no overlap with the heat region of the first tier die.

In accordance with other various exemplary embodiments, methods of dissipating heat in a multi-tier stacked integrated circuit may include establishing a thermal management floorplan for a first tier die, the thermal management floorplan defining a heat region having an area for thermal coupling to a heat sink, and defining locations within the heat region for heat generating components, generating a thermal management floorplan for a second tier die, the thermal management floorplan defining a shape and a dimension for the second tier die being stackable with the first tier die without substantial overlap of the heat region; and determining a thermal coupling element having a shape and a dimension to provide a thermal path between the heat region of the first tier die and a heat sink.

In an aspect, generating the thermal management floorplan for the second tier die defines the shape and the dimension for the second tier die that is stackable with the first tier die with no overlap of the heat region.

Methods according to various exemplary embodiments may include providing an initial design for the multi-tiered stacked integrated circuit, and selecting a target die of the initial design multi-tiered stacked integrated circuit to be the first tier die. In an aspect, the target die may have an initial floorplan. In one further aspect, generating the thermal management floorplan for the first tier die may comprise designating a region of the initial floorplan as the heat region, and moving heat sensitive components located within the heat region to locations away from the heat region. In another further aspect, generating the thermal management floorplan for the first tier die may comprise designating a region of the initial floorplan as the heat region, and moving heat-generating components located outside the heat region to locations within the heat region.

Methods according to various exemplary embodiments may further include identifying a die in the initial design multi-tiered stacked integrated circuit as an obstructing die, the obstructing die may have an initial floorplan defining an initial shape and an initial dimension, and may include designating the obstructing die to be the second tier die. Methods according to various exemplary embodiments may further include generating a non-obstructing thermal management floorplan for the second tier die.

In an aspect, generating the non-obstructing thermal management floorplan for the second tier die may comprise re-floorplanning the second tier die to be stackable with no overlap of the heat region.

In another aspect, generating the non-obstructing thermal management floorplan for the second tier die may comprise re-floorplanning the second tier die to be stackable without substantial overlap of the heat region.

Methods according to various exemplary embodiments may further include determining a heat sink and an arrangement for the heat sink relative to the second tier die stacked with the first tier die.

Various exemplary embodiments provide a multi-tier stacked integrated circuit including a first tier die having a heat region with a surface area, a second tier die stacked on the first tier die, the second tier die configured to not substantially overlap the heat region. A multi-tier stacked integrated circuit according to various exemplary embodiments may further include thermal coupling element thermally coupled to the surface area of the heat region, and a heat sink thermally coupled to the thermal coupling element, configured to form a thermal path from the heat region of the first tier die to the heat sink.

### BRIEF DESCRIPTION OF THE DRAWINGS

The accompanying drawings are presented to aid in the description of embodiments of the invention and are provided solely for illustration of the embodiments and not limitation thereof.

FIG. 1 is a cross-sectional view of one conventional multi-tier stacked IC, with an overlaying heat spreader.

FIG. 2A is a top view of an initial design of a multi-tier IC stack 200 having stacked IC dies with conventional floorplanning

FIG. 2B is a cross-sectional view of FIG. 2A from the FIG. 2A projection 2B-2B.

FIG. 3A is a top view of an optimized multi-tier IC stack according to an exemplary embodiment, after an optimizing floorplanning process is applied.

FIG. 3B is a cross-sectional view of FIG. 3A from the FIG. 3A projection 3B-3B.

FIG. 4A is a cross-section view of an optimized multi-tier IC package according to an exemplary embodiment, having thermal coupling, after an optimizing floorplanning process is applied.

FIG. 4B is a cross-section view of an optimized multi-tier IC package according to an alternative exemplary embodiment, having thermal coupling, after an optimizing floorplanning process is applied.

FIG. 5A is a top view of an optimized multi-tier IC stack according to another exemplary embodiment, after an optimizing floorplanning process is applied.

FIG. 5B is a cross-section view of FIG. 5A from the FIG. 5A projection 5B-5B.

FIG. 6A is a cross section view of an optimized multi-tier IC package according to another exemplary embodiment, having thermal coupling and non-zero overlay, after an optimizing floorplanning process is applied.

FIG. 6B is a cross section view of an optimized multi-tier IC package according to another alternative exemplary embodiment, having thermal coupling and non-zero overlay, after an optimizing floorplanning process is applied.

FIG. 7 is a cross section view of an optimized multi-tier IC package according to another alternative exemplary embodiment, comprising three stacked IC die and thermal coupling elements, after an optimizing floorplanning process is applied.

FIG. 8 shows a floorplan optimization process for optimized multi-tier IC stack and optimized package according to an exemplary embodiment.

FIG. 9 shows a fabrication process for optimized multi-tier IC stack and optimized package according to an exemplary embodiment.

FIG. 10 is a block diagram illustrating one design workstation for semiconductor IC dies and packages according to various exemplary embodiments.

FIG. 11 shows an exemplary wireless communication system in which one or more embodiments of the disclosure may be advantageously employed.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for purposes of describing examples of particular embodiments. The terminology used herein is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

The term package substrate means any structure for supporting an IC die or supporting a multi-tier IC die stack, unless expressed otherwise. The terms “first tier die”, “second tier die” and/or “third tier die” mean tiers of die in a multi-stack package. It will be understood that the notation “first”, “second”, “third”, etc., does not necessarily indicate a positional or geographical location of an IC die. For example, a first tier die does not necessarily mean the die is located at the bottom of an IC die stack or that the die is located at the top of an IC die stack. The terms “attached to”, “secured to”, “on” and “coupled” do not require that the structures be in direct contact, unless expressed otherwise.

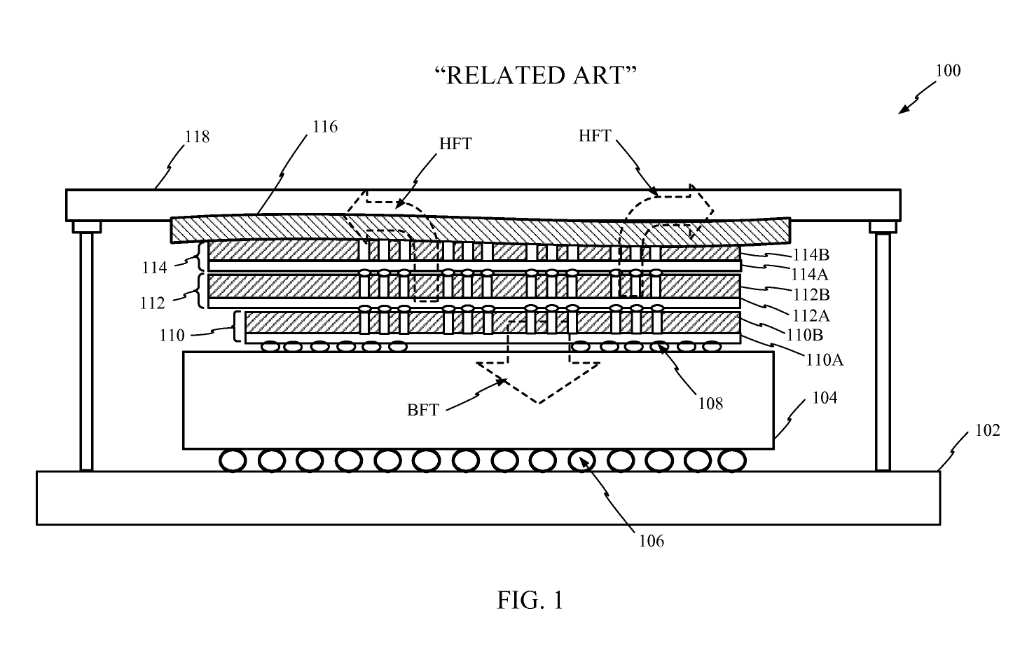

FIG. 1 shows a cross section of a conventional multi-tier IC package 100, having a package substrate 104 mounted on and coupled to a printed circuit board 102. The package substrate 104 can be coupled to the printed circuit board 102 through solder balls, of which item 106 is representative. A first tier IC die 110 with active layer 110A and substrate layer 110B is connected to the package substrate 104 by solder bumps or copper pillars 108 (not separately shown). Through substrate vias (TSVs) couple to the first tier IC die 110 to a second tier IC die 112. TSVs may also couple the second tier IC die 112 to a third tier IC die 114. The TSVs are formed within the die substrate (e.g., 110B, 112B) according to conventional or known techniques. The TSVs extend from solder pads (not shown) on the active layer of a die (e.g., 112A, 114A) to metal landing pads on the top surface of the substrate layers. Micro solder bumps (shown but not separately numbered) can couple the solder pads on the bottom surface of the substrate layer, for example 110B, to corresponding pads (not explicitly shown) on the surface of the active layer, for example, 112A of a second tier IC die 112.

The second tier IC die 112 can have pads (not separately shown) on the top surface of its substrate layer 112B. The 112B pads may be coupled to pads on the 114 die's active layer 114A. The 112B and 114A pads may be coupled, for example by TSVs (such as the examples shown but not labeled). A third or top tier IC die 114 can be above the second tier IC die 112. The third IC die 114 may, for example, be provided face down with its active layer 114A against the top surface of the second tier IC's substrate layer 112B and its substrate layer 114B as a top surface.

It will be understood that TSVs are only one example means for coupling a die to another die or to a package substrate. Other techniques, for example multi-level wire bonding and other known methods may be used to interconnect dies and packages. For example, multi-level wire bonding can be used according to conventional techniques, and therefore further detailed description is omitted.

The active layers 110A, 112A and 114A can include any of various integrated circuits arranged for example in blocks, modules, subsystems and the like, according to any conventional floorplan. As illustrative examples, the active layer 110A of the first tier IC die 110 can include random access memory (RAM), and/or one or more ARM or comparable type processor cores (not shown), register arrays (not shown), digital signal processing (DSP) modules (not shown), analog-to-digital converters (ACS) (not shown), and radio frequency signal demodulators and decoders (not shown). The active layers 112A and 114A of the second tier IC die 112 and third tier IC die 114 can likewise include any integrated circuits. The technology, floorplan and fabrication of such conventional integrated circuits can be according to conventional techniques known to persons of ordinary skill in that art and, therefore, further detailed description is omitted.

Continuing to refer to FIG. 1, a thermally conductive element 116 such as a thermally conducting sponge can be included, to carry heat from a surface of an integrated circuit (e.g., the top of the third tier IC die 114) to a heat spreader 118. Example heat flow of the FIG. 1 device will now be described. The heat flow labeled “HFT” may flow in the direction of the heat spreader 118 and may be generated in the third tier IC die 114 combined with heat generated by underlying tiers (e.g., the second tier IC die 112). The heat flow HFT can pass through the thermally conductive element 116 and into the heat spreader 118. The heat flow labeled “BFT” may flow in the direction of the package substrate 104 and may be generated in the first tier IC die 110 combined with a portion of the heat generated by the overlaying tiers (e.g., second tier IC die 112).

In the structure of FIG. 1, dissipation of the BFT heat through the package substrate 104 is difficult due to the fact that the materials selected for package substrates often has high thermal resistance. Package substrate material may be formed of organic laminate, silicon, glass, sapphire or other materials selected for physical characteristics particular to the functions of substrates (e.g., certain ranges of dielectric and thermal expansion coefficients), and therefore the substrate often has high thermal resistance. One cost of the above-described conventional multi-tier stack having high thermal resistance, can be the imposition of design constraints to avoid unacceptable heat level in an IC die. For example, there may be a lowering of a bound on transistor count or density, and/or a reduction in switching rate of circuits over what may be attainable if greater heat conduction could be provided. These types of design constraints are undesirable.

Various exemplary embodiments of the invention address these and other issues, by providing improved thermal management floorplan structures and methods, which allow for lowered thermal resistance and improved heat dissipation in a multi-tier stacked IC package. As will be described in further detail, the design process may begin with an initial floorplan design of stacked IC dies. After determining a heat profile of the IC stack (i.e., the initial floorplan), a target IC die may be identified for additional cooling. It will be understood throughout this disclosure that the target IC die or a portion of the target IC die may be the heat source or, alternatively, the target IC may be affected by some other heat source. For example, the target IC die itself may have no substantial heat source but may have “sensitive circuitry” which is affected by some other heat source. The target IC die is then optimized for thermal management, becoming an “optimized IC die”. In an aspect, such optimization includes re-floorplanning the target IC die to a thermal management floorplan by, for example, shifting or otherwise re-arranging identified high power circuitry heat sources into designated heat regions. Alternatively or in combination with the above, re-floorplanning for such optimization may include re-arranging sensitive areas of the IC die (which are not heat sources themselves) to an area on the optimized IC die located away from the designated heat region. It will be understood that the target IC die and the optimized IC die may be any tier on the multi-tier IC stack, and that there may be more than one such die within the stack. Further, it will be understood that the term “optimized” relates generally to improvements and does not require an absolute maximum of any parameter.

It will be understood that throughout this disclosure the terms “floorplanning” and “re-floorplanning” include any one of, and any combination of shifting or otherwise adjusting the geographic location within the IC die of components and interconnections, and/or adjusting, shaping or sizing of the IC die components and interconnections.

Various exemplary embodiments can include other IC dies that may be arranged within the multi-tier stacked IC package to have zero overlap or only partial overlap with the designated heat regions of the optimized IC die. A heat sink may be provided through a heat spreader overlaying the top most IC die or through the package substrate. Thermal coupling elements provide thermal coupling between the IC dies and either the heat spreader heat sink or the package substrate heat sink, thereby resulting in improved thermal heat flow.

It will be understood that the stacked IC dies of this disclosure may be interconnected by various technologies including TSVs (e.g., TSVs formed by any known methodologies such as via first, via last, via middle) or wire bonding or a combination thereof. This disclosure is not limited by any die to die interconnect technology because this disclosure is widely applicable to any die-to-die or die-to-package substrate interconnects. Moreover, it will be understood that the stacked IC dies of this disclosure may be oriented in various directions (e.g., active side of die facing up, active side of die facing down relative to other dies or package substrates) and in various combinations thereof. This disclosure is not limited by any directional orientation of a die relative to another die or package substrate. On the contrary, practices according to this disclosure are applicable to all die orientations.

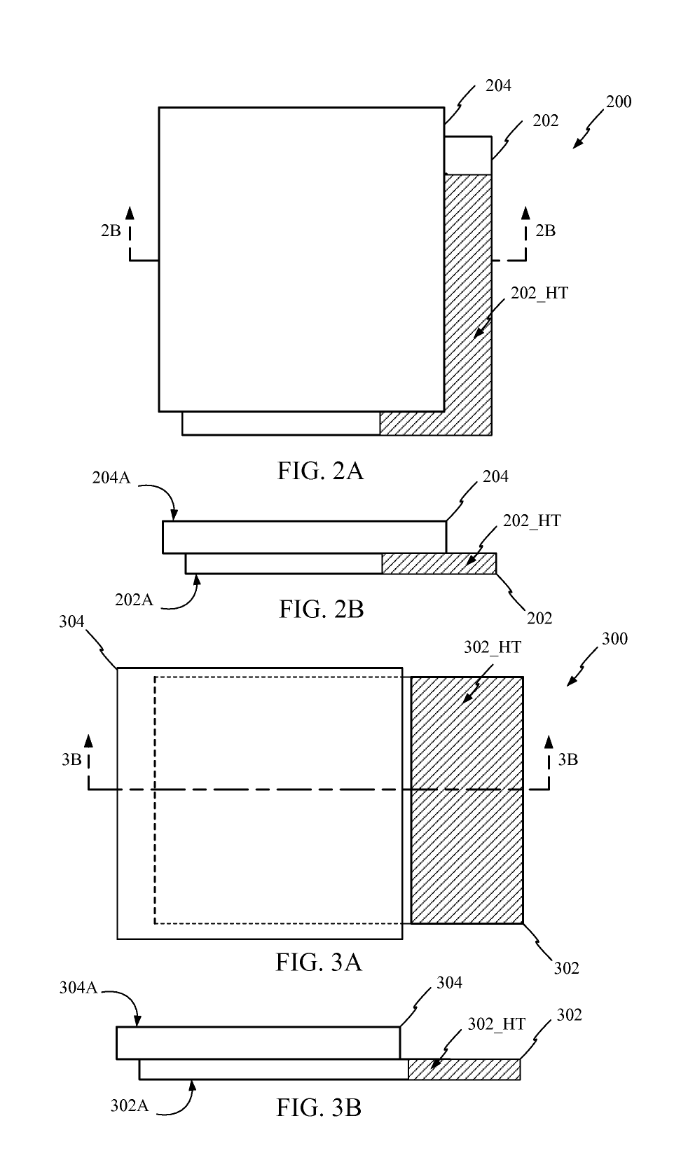

FIG. 2A is a top view of an initial design of a multi-tier IC stack 200 having stacked IC dies with conventional floorplanning Multi-tier IC stack 200 has two dies, IC die 202 and another IC die 204. FIG. 2B is a side view from the FIG. 2A projection 2B-2B. IC die 202 may be identified as a target IC die 202 based on a computer simulation or based on empirical data or other techniques known to persons of ordinary skill in the art, which indicate that IC die 202, may have a heat region 202_HT. It will be understood that target IC die 202 may be the source of the heat region 202_HT or target IC die 202′s heat region 202_HT may originate from some other heat source.

In one embodiment shown in FIG. 2A and FIG. 2B, the multi-tier IC stack 200 may be provided on a package substrate (not shown). In such an embodiment, one surface area 202A of the target IC die 202 would be provided on a surface of the package substrate. IC die 204 would be provided as a second tier die over IC die 202. A heat spreader (not shown) may overlay the IC die 204. In the initial design shown in FIG. 2A and 2B, a portion of IC die 204 significantly overlaps the heat region 202_HT of the target IC die 202. The circuitry on IC die 204 may become heated due to the overlap with the heat region 202_HT and such heating may be undesirable. Moreover, it may be desirable to increase the ability of IC die 202 to dissipate heat from its heat region 202_HT.

In another embodiment not shown, one surface area 204A of the IC die 204 may be provided on a surface of the package substrate (not shown). IC die 202 would be provided stacked over IC die 204. In such an initial design, a portion of IC die 204 would significantly overlap the heat region 202_HT of the target IC die 202. As described in the preceding paragraph, the circuitry on IC die 204 may become heated due to overlap with the heat region 202_HT and such heating may be undesirable. Moreover, it may be desirable to increase the ability of IC die 202 to dissipate heat from its heat region 202_HT. Due to the significant overlap, heat flow from at least a portion of the heat region 202_HT to the package substrate will be impeded resulting in high thermal resistance, and making heat dissipation difficult.

FIG. 3A is a top view of an optimized multi-tier IC stack 300 according to an exemplary embodiment, after a thermal management optimizing floorplanning process is applied. FIG. 3B is a cross-section of FIG. 3A of projection 3B-3B. The thermal management optimized multi-tier IC stack 300 includes IC die 302 having a thermal management optimized die floorplan comprising a designated heat region 302_HT. For brevity, optimizing a floorplan of an IC die to have a thermal management optimized die floorplan comprising a designated heat region will herein be alternately referred to as “optimizing floorplanning process.” Likewise, for brevity, a thermal management optimized die floorplan comprising a designated heat region will herein be referred to as “optimized floorplan,” and an IC die having a thermal management optimized die floorplan comprising a designated heat region will herein be alternately referred to as “optimized floorplan” or “thermal management floorplan.”

Referring to FIG. 3A, optimized multi-tier IC stack 300 can also include a second die 304 having an arrangement (i.e., having a size and geographical location relative to other FIG. 3A structures) and floorplan so as not to overlap the designated heat region 302_HT. The optimized floorplan of optimized IC die 302 may be generated by a re-floorplanning of the FIG. 2A target IC die 202. The re-floorplanning can be configured to move high heat generating circuitry (not separately depicted in the figures) of the FIG. 2A target IC die 202 from the heat region 202_HT to the designated heat region 302_HT. In such a case, the second die 304 may be floorplanned and arranged so as not to overlap the designated heat region 302_HT. Alternatively, the optimized IC die 302 may not necessarily be the primary heat source but may have circuitry sensitive to heat generated by some other heat source. In such an embodiment, the target IC die 202 may be re-floorplanned so that any sensitive circuitry is moved away from the designated heat region 302_HT. It should be understood that the optimized IC die 302 may include combinations of disclosed re-floorplanning and/or re-arrangement.

In an aspect, re-floorplanning of IC die 204 may be performed, if necessary, subsequent to or concurrent with re-floorplanning and/or re-arranging of IC die 202, resulting in the optimized multi-tier IC stack 300. In one embodiment as depicted in FIG. 3A and 3B, IC die 304 may comply with a perimeter of which IC die 304 may overlap with optimized IC die 302. For example, IC die 304 may overlap with a portion (i.e., a permitted perimeter) of optimized IC die 302, but not including the portion of optimized IC die 302 that is the designated heat region 302_HT. In other words, in one exemplary embodiment, there is substantially zero overlap of IC die 304 with the designated heat region 302_HT. The substantially zero overlap is illustrated by FIG. 3B. Other arrangements of IC die 304 relative to optimized IC die 302 where IC die 304 does not substantially overlap with 302_HT, are within the scope of this disclosure.

In an aspect, the optimized multi-tier IC die stack 300 may be supported on a package substrate (not shown). In one arrangement, one surface area 302A of the optimized IC die 302 can be provided on a surface of the package substrate. In such an arrangement, IC die 304 may be coupled over optimized IC die 302 and arranged so as not to overlap with 302_HT. A heat spreader (not shown) may be provided on the IC die 304, and may extend the length or beyond (in the horizontal axis) of optimized IC die 302 or may extend the length or beyond of IC die 304. In an alternative aspect (not shown), a surface area 304A of IC die 304 can be provided on a surface of the package substrate, and the optimized IC die 302 can be provided on IC die 304.

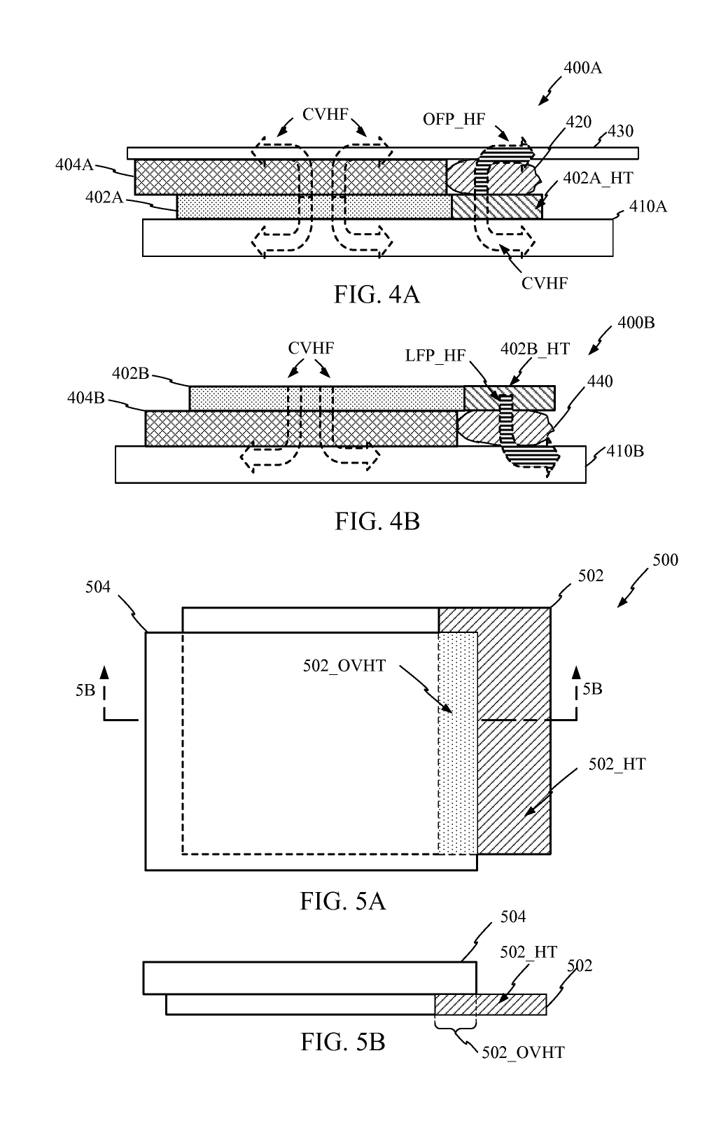

FIG. 4A is a cross-section view of an optimized multi-tier IC package 400A according to an exemplary embodiment, having thermal coupling, after an optimizing floorplanning process is applied. Optimized muti-tier IC package 400A may have optimized IC die 402A (i.e., IC die having optimized floorplan) provided on package substrate 410A. The optimized IC die 402A may include a designated heat region 402A_HT. The floorplan of optimized IC die 402A, after the optimizing process, may be the same as for previously described optimized IC die 302. The optimized multi-tier IC package 400A includes IC die 404A having, in an aspect, a floorplan and arrangement so as not to overlap the designated heat region 402A_HT of optimized IC die 402A. IC die 404A may be optimally arranged the same as previously described for IC die 304 and in such a way that the arrangement of IC die 404A results in an optimized multi-tier IC package 400A. Heat spreader 430 may be provided over and thermally coupled to IC die 404A. It will be understood that the FIG. 4A specific configuration of heat spreader 430 is only one example heat sink that can be used in practices according to this disclosure. For example, any conventional or non-conventional known heat spreader techniques and methods that act as a heat sink may be used in place of heat spreader 430 and are within the scope of this disclosure.

The optimized multi-tier IC package 400A can include a thermal coupling element 420.

In an aspect, thermal coupling element 420 may be configured and arranged such that it thermally couples the designated heat region 402A_HT of optimized IC die 402A to the heat spreader 430. It will be appreciated that the thermal coupling element 420 in accordance with various exemplary embodiments may provide a low thermal resistance path from a heated region to a heat sink, thereby providing a means of increased heat dissipation. In one embodiment, the thermal coupling element 420 may be in direct contact (i.e., direct thermal coupling) with both optimized IC die 402A and heat spreader 430. This provides for heat from optimized IC die 402A to be dissipated through heat spreader 430. In another embodiment, the thermal coupling element 420 may be directly coupled to at least a portion of optimized IC die 402A or to package substrate 410A. In other embodiments, the thermal coupling element 420 may be indirectly coupled to, but not be in direct contact with the heat spreader 430 or the designated heat region 402A_HT.

In the above-mentioned embodiments, the thermal coupling element 420 provides for low thermal resistance so that heat may flow away from heat region 402A_HT or other designated heat regions. According to various exemplary embodiments, the thermal coupling element 420 can comprise a thermal interface material (TIM) such as a thermally conductive plastic, thermally conductive putty such as SARCON® silicone putty available from Fujipoly®, or any of various similar type materials available from various vendors. In other aspects, the thermal coupling element 420 can be formed of a metal; a semiconductor; a thermally conductive paste or grease; a thermally conductive tape; a phase change material; graphite; and/or a carbon nanotube material. It will be understood that these example materials for the thermal coupling element 420 are illustrative and are not a limit on materials that can be used. It will also be understood that selection of the material and structure for the thermal coupling element 420 may be application specific. The selection can be readily performed by persons of ordinary skill in the art having view of this disclosure, based on factors readily ascertainable by such persons, for example, temperature range, package dimensions, e.g., spacing between the heat spreader 430 and the surface of the heat region 402A_HT.

With continuing reference to FIG. 4A, it will be appreciated that the thermal coupling element 420 can provide a low thermal resistance path so that heat flow OFP_HF may flow from the designated heat region 402A_HT of the optimized die floorplan of IC die 402A to the heat spreader 430. The heat flow path OFP_HF may substantially supplement the conventional heat flow CVHF from the designated heat region 402A_HT to the package substrate 410A. Accordingly, aspects of this disclosure may be combined (e.g., the optimized IC die, optimized die arrangement, heat spreader and thermal coupling element may be combined) as in FIG. 4A for improved heat dissipation.

FIG. 4B is a cross-section view of an optimized multi-tier IC package 400B according to an alternative exemplary embodiment, having thermal coupling, after a thermal management optimizing floorplanning process is applied. The optimized multi-tier IC package 400B may include a package substrate 410B supporting a first tier die, IC die 404B, and supporting a second tier die, IC die 402B having an optimized die floorplan including a designated heat region 402B_HT. The optimized IC die 402B can be the same as previously described FIG. 3A optimized IC die 302. Likewise, IC die 404B may be floorplanned and/or arranged, for example as previously described in reference to the FIG. 3A IC die 304, such that IC die 404B results in an optimized multi-tier IC package 400B. In other words, IC die 404B may be arranged and floorplanned such that it does not overlap with the designated heat region 402B_HT of optimized IC die 402B.

The optimized multi-tier IC package 400B can include a thermal coupling element 440.

The thermal coupling element 440 can be arranged such that it thermally couples the designated heat region 402B_HT of optimized IC die 402B to the package substrate 410B. In one embodiment, the thermal coupling element 440 may be in direct contact with both optimized IC die 402B and the package substrate 410B. Such an embodiment provides reduced thermal resistance, thereby providing a means for heat dissipation. In another embodiment, the thermal coupling element 440 may be located directly under at least a portion of optimized IC die 402B. In another embodiment, the thermal coupling element 440 may be provided over a package substrate 410B. In other embodiments, the thermal coupling element 440 may be indirectly coupled to either designated heat region 402B_HT or the package substrate 410B, or both. The thermal coupling element 440 can be formed, for example, as previously described for the thermal coupling element 420.

The thermal coupling element 440 can provide a low thermal resistance heat path so that heat flows from the designated heat region 402B_HT of optimized IC die 402B through the package substrate 410B. This heat flow is identified as LFP_HF for convenience. The heat flow path LFP_HF may substantially supplement heat flow CVHF from a portion of the optimized IC die 402B to the package substrate 410B. Moreover, a heat spreader (not shown) may be provided over optimized IC die 402B, allowing for additional heat dissipation of optimized IC die 402B.

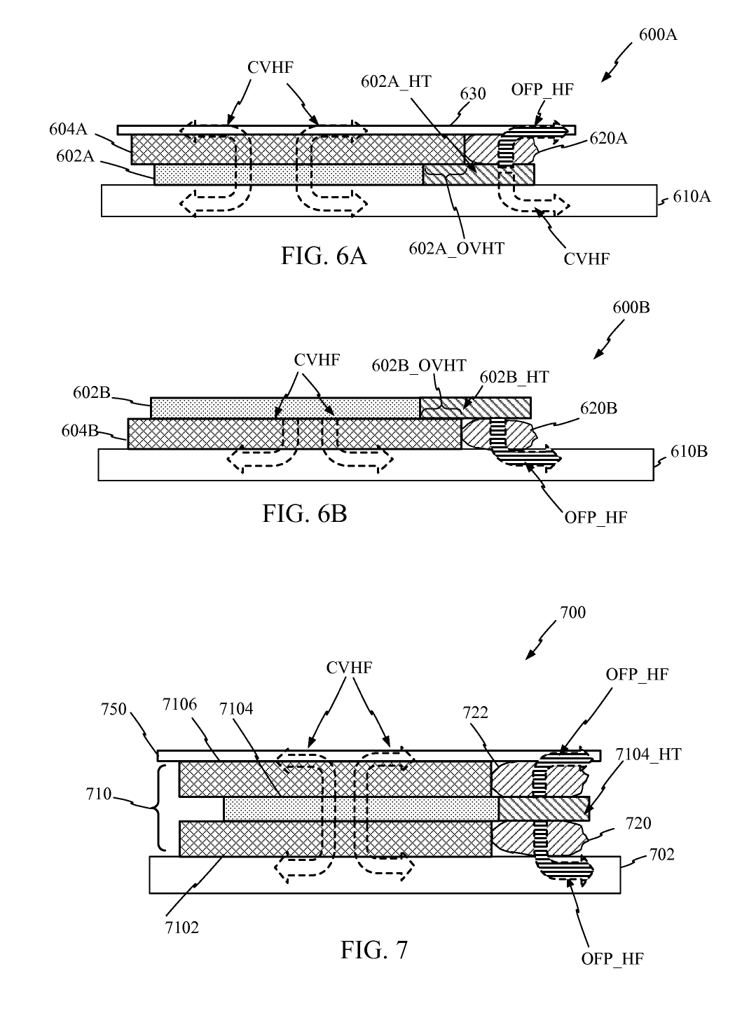

Exemplary embodiments described above in reference to FIGS. 3A-3B show the designated heat region 302_HT as not being overlapped by any other die within the multi-tiered package. In other words, FIGS. 3A-3B show the IC die 304 as having zero overlap of the designated heat region 302_HT of IC die 302. Similarly, the embodiment described in FIG. 4A shows the heat region 402A_HT of optimized IC die 402A as not being overlapped by any other die within the multi-tier package (i.e., IC die 404B does not overlap 402B_HT). Practices according to one or more embodiments may include instances wherein the “zero overlap” described above cannot be obtained, or may be deemed not necessary. For example, a zero overlap may be deemed not necessary for a given application, because the designated heat region can be sufficiently cooled with only a portion of its surface area having contact with the thermal coupling element. Practices according to various exemplary embodiments may therefore provide for an IC die that partially overlaps a designated heat region of an optimized die floorplan of an IC die. Accordingly, the processes described earlier may be modified such that a given percentage of overlap occurs as opposed to the previously described zero overlap. Examples according to this exemplary embodiment will be described in reference to FIGS. 5A, 5B, 6A and 6B.

FIG. 5A is a top view of an optimized multi-tier IC stack 500 according to another exemplary embodiment, after an optimizing floorplanning process is applied. FIG. 5B is a cross-section view of FIG. 5A projection 5B-5B. Optimized multi-tier IC stack 500 may include optimized IC die 502 having an optimized floorplan including a designated heat region formed of regions 502_OVHT and 502_HT, and an IC die 504. The region 502_HT is not overlapped and is thereby directly accessible by a thermal couple, as previously described. The region 502_HT will therefore be referenced as the designated non-overlapped heat region 502_HT. The region 502_OVHT, though, may be overlapped by IC die 504. This can arise because the IC die 504, although re-floorplanned and arranged to provide access to the designated heat region of IC die 502 cannot, for reasons such as described above, have zero overlap of region 502_OVHT. Instead, the IC die 504 has a floorplan and arrangement that, in accordance with an exemplary embodiment will not overlap the designated non-overlapped heat region 502_HT, but may partially overlap region 502_OVHT. The region 502_OVHT will therefore be referred to as “the designated overlapped heat region” 502_OVHT.

In an embodiment, floorplanning processes for FIGS. 5A and 5B optimized multi-tier

IC stack 500 may begin with IC dies as depicted at FIG. 2, i.e., the target IC die 202 (identified for thermal management) and the IC die 204. In an aspect, the floorplanning processes can include one or both of the previously described optimized re-floorplanning of the FIG. 2A target IC die 202 and arrangement of other IC dies either above or below the target IC die 202 such that they partially overlap with a designated hot area. The process may include identifying a specific ratio or percentage relationship to quantitatively define the designated non-overlapped heat region 502_HT and the designated overlapped heat region 502_OVHT region. For example, designated non-overlapped heat region 502_HT may be designated as 75% of the heat region and the designated overlapped heat region 502_OVHT may be designated as 25% of the heat region. It will be understood that the FIG. 5A and 5B depiction of the relative area of the designated non-overlapped heat region 502_HT and the designated overlapped heat region 502_OVHT is an arbitrary example, and is not intended to limit the scope of any embodiment. Regarding actual numerical ranges of the area of designated overlapped heat region 502_OVHT relative to the area of designated non-overlapped heat region 502_HT, it will be appreciated by persons of ordinary skill in the art having view of this disclosure that the range can be application-specific. However, such persons can readily identify a percentage relation, as well as the actual areas without undue experimentation using, for example, computer simulation tools readily available from various vendors.

FIG. 6A is a cross section view of an optimized multi-tier IC package 600A according to another exemplary embodiment, having thermal coupling and non-zero overlay, after an optimizing floorplanning process is applied. The optimized multi-tier IC package 600A may have a package substrate 610A supporting an optimized IC die 602A including a designated heat region comprising two regions: designated overlapped heat region 602A_OVHT and designated non-overlapped heat region 602A_HT. The optimized IC die 602A may be the optimized IC die 502 described in reference to FIGS. 5A and 5B. The optimized multi-tier IC package 600A also has IC die 604A that, similar to the above-described IC die 504, has been floorplanned to provide access to the designated heat region of the optimized IC die 602A. However, for reasons described in reference to IC die 504, IC die 604A partially overlaps designated overlapped heat region 602A_OVHT but does not overlap designated non-overlapped heat region 602A_HT. The IC die 604A can be, for example, the previously described IC die 504.

Heat spreader 630 is provided over IC die 604A. It will be understood that the particular configuration and arrangement of the heat spreader 630 is only one example, and that embodiments are not limited to that example. On the contrary, persons of ordinary skill in the art, upon reading the present disclosure, may readily identify various alternative configurations and arrangements, and will appreciate that selection may be application specific and may, at least in part, be a design choice. Persons of ordinary skill in the art, though, can readily identify various alternative configurations and arrangements to implement the heat spreader 630, by applying general engineering methodology such persons possess to this disclosure.

In an aspect, a thermal coupling element 620A can be arranged to thermally couple the overlaying heat spreader 630 and optimized IC die 602A. For example, thermal coupling element 620A may thermally couple designated non-overlapping heat region 602A_HT to the heat spreader 630 in a manner similar to FIG. 4A element 420. As shown in FIG. 6A, in one example arrangement the thermal coupling element 620A does not overlay the designated overlapping heat region 602A_OVHT of the optimized IC die 602A. The thermal coupling element 620A provides a low thermal resistance path so that heat flow OFP_HF may flow out of the optimized IC die 602A through the thermal coupling element 620A and heat spreader 630. The heat flow path OFP_HF provides supplemental heat dissipation for heat flow out of the package substrate 610A. In additional aspects, the thermal coupling element may be directly thermally coupled to one or both of the heat spreader 630 and the designated non-overlapping heat region 602A_HT of the optimized IC die 602A. Alternatively, the thermal coupling element 620A may be indirectly thermally coupled to one or both of the heat spreader 630 and optimized IC die 602A. In an aspect, the thermal coupling element 620A may be indirectly thermally coupled to the heat spreader 630, the designated overlapping heat region 602A_OVHT and the designated non-overlapping heat region 602A_HT. In any of the aspects, thermal coupling element 620A acts as a means for heat dissipation.

FIG. 6B is a cross section view of an optimized multi-tier IC package 600B according to another alternative exemplary embodiment, having thermal coupling and non-zero overlay, after an optimizing floorplanning process is applied. The optimized multi-tier IC package 600B can have a package substrate 610B coupled to a first tier IC die 604B and an optimized IC die 602B. The optimized IC die 602B, similar to the FIG. 6A optimized IC die 602A, has an optimized die floorplan including a designated heat region comprising two regions: designated overlapping heat region 602B_OVHT and designated non-overlapping heat region 602B_HT. The IC die 604B may be floorplanned and arranged (e.g., sized, shaped and/or moved in geographical location relative to other FIG. 6A IC dies) not to overlap the designated non-overlapping heat region 602B_HT of optimized IC die 602B but, for reasons as previously described, may overlap the designated overlapping heat region 602B_OVHT. In an aspect, a thermal coupling element 620B may directly thermally couple the package substrate 610B to at least a portion of the designated non-overlapping heat region 602B_HT of optimized IC die 602B.

As depicted in the FIG. 6B example arrangement, thermal coupling element 620B may contact less than 100% of the entire designated non-overlapping heat region 602B_HT.

However, a contact area can be readily selected that is sufficient to provide a low thermal resistance path OFP_HF for heat to flow from the optimized IC die 602B through the thermal coupling element 620B and package substrate 610B. Such a path allows heat to be dissipated through the package substrate 610B. It will be understood that optimized multi-tier IC package 600B can include a heat spreader (not shown) overlaying the optimized die floorplan of IC die 602B. Such a heat spreader would provide supplemental heat dissipation for optimized multi-tier IC package 600B.

FIG. 7 is a cross section view of an optimized multi-tier IC package 700 according to another alternative exemplary embodiment, comprising three stacked IC die and thermal coupling elements, after an optimizing IC die floorplanning and arranging process is applied. The optimized multi-tier IC package 700 may include a package substrate 702 supporting a multi-tier IC die stack 710. The optimized multi-tier IC die stack 710 may comprise IC die 7102, IC die 7104 and IC die 7106 (for convenience in description IC dies 7102, 7104 and 7106 may be referred to as “first tier”, “second tier” and “third tier,” respectively), and a heat spreader 750 overlaying the IC die 7106. In an aspect, the heat spreader 750 can be in accordance with conventional technology and therefore, further detailed description is omitted. It will be understood that a conventional technology implementation of the heat spreader 750 can include a thermal coupling sponge or equivalent resilient element (not separately shown).

Referring still to FIG. 7, in an aspect, the middle tier die is shown as an optimized IC die 7104 having an optimized die floorplan including a designated heat region 7104_HT. Optimized IC die 7104 may apply any of the concepts described in reference to FIGS. 3A, 3B, 4A, 4B, 5A, 5B, 6A and 6B. In a related aspect, the IC die 7102 that separates the optimized IC die 7104 from the package substrate 702 may be floorplanned and arranged (e.g., sized, shaped and/or moved in geographical location relative to other FIG. 6A IC dies) such that it has zero overlap with the designated heat region 7104_HT of optimized IC die 7104. The arrangement of IC die 7102 and optimized IC die 7104 with respect to each other can be provided by applying clearance floorplanning concepts as described in reference to FIGS. 3A, 3B, 4B, and 6B. In a further aspect, IC die 7106 that separates the optimized IC die 7104 from the heat spreader 750, may be arranged (i.e., one or more of re-floorplanned, re-sized, and/or moved in geographical location of the die relative to another die) such that it has zero overlap with the designated heat region 7104_HT of optimized IC die 7104.

Among other features, the FIG. 7 optimized multi-tier IC package 700 provides an accommodating space for one or more thermal coupling elements to establish a thermal path from optimized IC die 7104 to the heat spreader or to the package substrate, or to both. For example, in an aspect, thermal coupling element 720 may be configured and arranged to provide a thermal path from optimized IC die 7104 through thermal coupling element 720 to the package substrate 702. For example, the thermal coupling element 720 may be directly or indirectly coupled under a portion of the optimized IC die 7104, such as under the designated heat region 7104_HT, and directly or indirectly coupled to a surface of the package substrate 702. The coupling can be similar to that established by the FIG. 4B thermal coupling element 440. In another aspect, thermal coupling element 722 may be configured and arranged to provide a thermal path from optimized IC die 7104 to the heat spreader 750. For example, the thermal coupling element 722 may be directly or indirectly coupled over a portion of the optimized IC die 7104, such as over the designated heat region 7104_HT, and directly or indirectly coupled to a surface of the heat spreader 750. The coupling can be similar to that established by the FIG. 4A thermal coupling element 420.

FIG. 7 shows both IC dies 7102 and 7106 respectively, as having zero overlap with the designated heat region 7104_HT of optimized IC die 7104. It will be understood that either or both the first tier IC die 7102 or third tier IC die 7106 can be alternatively floorplanned and/or arranged so as to partially overlap with designated heat region 7104_HT of optimized IC die 7104 as described in reference to FIGS. 5A, 5B, 6A and 6B.

Moreover, it will be understood that the concepts shown in FIG. 7 or discussed above are not limited to the particular structure shown in FIG. 7. For example, heat dissipation concepts of FIG. 7 may be applied in an alternative exemplary embodiment (not shown), having three IC dies stacked in an arrangement (not shown) comprising an optimized IC die on the topmost tier (i.e., tier 3), an optimized IC die on the bottommost tier closest to the package substrate (i.e., tier 1), and a middle IC die. In the alternative exemplary embodiment, the middle IC die may be, according to one aspect, floorplanned and arranged to have zero overlap with the designated heat regions of either tier 1 or tier 2 or both. In another aspect of this alternative exemplary embodiment, which may be combined with the previously described aspect, the middle IC die may be floorplanned and arranged to have non-zero (i.e., some) overlap with the designated heat region of either tier 1 or tier 2 or both. In this alternative exemplary embodiment (not shown), the thermal coupling element may be provided within an accommodating space between the designated heat regions of the first and third tiers. Then, heat dissipation can occur through various low thermal paths including from the first tier optimized IC die through the thermal coupled element and optional heat spreader, or from the third tier optimized IC die through the thermal coupled element and package substrate. These heat dissipations would be supplemental to heat dissipation occurring from the optimized die's nearest heat sink (e.g., third tier optimized die is closest to the optional heat spreader and therefore heat from the third tier would be dissipated through that path).

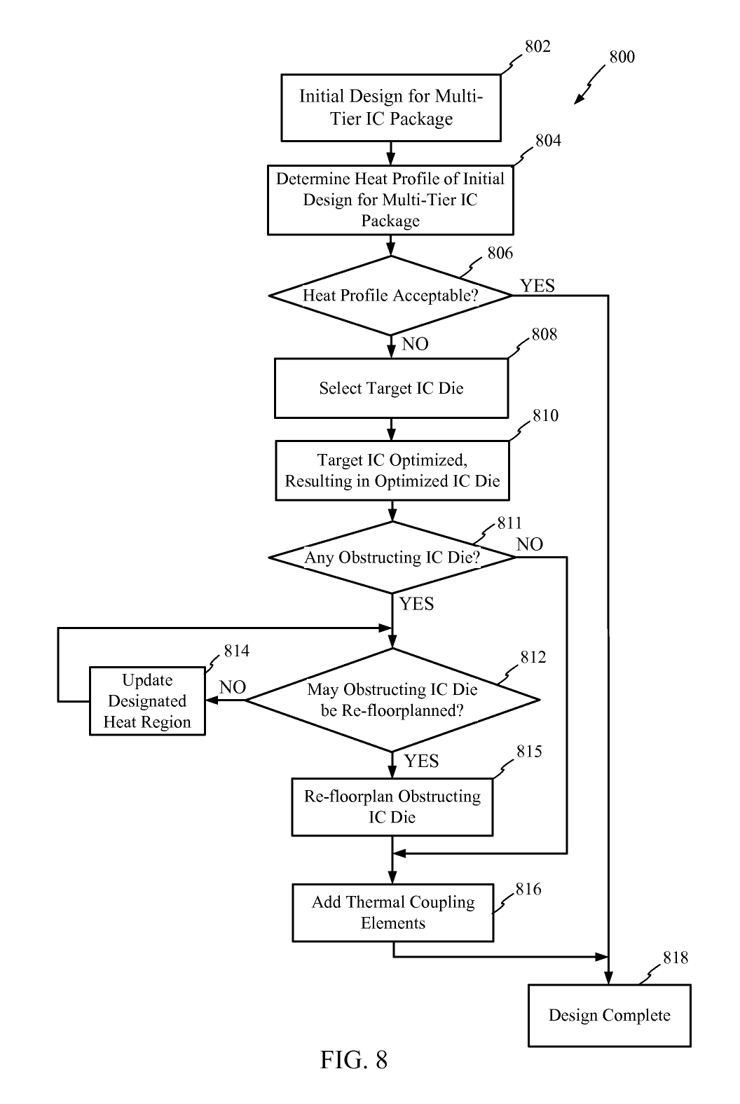

FIG. 8 shows a floorplan optimization process 800 for optimized multi-tier IC stack and optimized package according to an exemplary embodiment. The floorplan optimization process 800 begins with a starting or initial design for a multi-tier IC package, shown as process 802. Such initial design includes an initial floorplan for each IC die in the multi-tier stack and physical arrangement of each IC die on the x-axis (with respect to any other IC dies either above or below or both) and y-axis. Such initial design also includes a packaging substrate and an optional heat spreader. After process 802 is performed, the heat profile is determined at process 804. In an exemplary embodiment, the starting or initial design multi-tier IC package can be input to a computer simulation module or equivalent implementation, for example, in a computer simulation engine. The computer simulation engine may be a commercially available IC simulation engine such as the Apache Sentinel-TI™ available from ANSYS Inc. or any of various comparable computer simulation engines available from other vendors. Persons of ordinary skill in the art having view of this disclosure can readily select from such commercially available computer simulation engines to practice according to the exemplary embodiments. Such computer simulation may generate a temperature profile for the initial design of process 802. The temperature profile may span a given range of operating conditions. Techniques for modeling and for operating the computer simulation engine to generate the temperature profile can be in accordance with general techniques known to persons of ordinary skill in the art. Alternatively, the heat profile modeling at 804 may be performed by any other method known by persons of skill in the art, including by empirical heat data and/or manual calculations.

After the generation of the temperature profile at 804, a decision or identification occurs at 806 as to whether the heat profile is acceptable. For example, the decision may be based on given maximum temperature and/or temperature gradient criteria. If the answer is “YES”, the design may be deemed complete at 818. If the answer at 806 is “NO,” for example due to non-acceptable hot spots in one or more IC dies, the process may go to 808 to select a target IC die for additional thermal management and heat dissipation. According to exemplary embodiments, more than one target IC die may be selected for thermal management as discussed with reference to alternative embodiments of FIG. 7 but not shown. In other various exemplary embodiments, the target IC die may be any IC die within a multi-die stack (i.e., it may be a first tier die, a second and/or third tier die, it may be a top die, bottom die or middle die etc.) which is identified for additional thermal management. It will be understood that the target IC die or a portion of its circuits may be the heat source itself. Alternatively, the target IC die may have circuitry sensitive to heat (coming from some other heat source), such that the target IC die is identified for additional thermal management.

After selecting the target IC die at 808, the target IC die is optimized at 810 to have a thermal management floorplan according to concepts described in FIG. 3A. The output of process 810 results in an optimized IC die (or multiple optimized IC die). In FIG. 3A the target die 202A of FIG. 2A is optimized by, for example, re-floorplanning the die such that heat sources on target IC die are in a designated heat region. In other exemplary embodiments of 810, the optimized IC die may be such that all or a percentage of the identified hot spots of 806 are moved, shifted or otherwise adjusted in location by a re-floorplanning to be in the designated heat region. In another exemplary embodiment of 810, which may be in combination with the above, such optimization may include re-floorplanning to move, shift or otherwise adjust in location sensitive areas of the target IC die (which are not heat sources themselves) to an area on the IC die located away from the designated heat region. It is therefore understood, that “re-floorplanning” can include reshaping, shifting and/or resizing of components and interconnections. In an exemplary embodiment, the optimized IC die of 810 may be the result of applying the concept of relocating identified portions of the die (e.g., identified heat regions or portions of the die which are sensitive to heat) to a designated heat region or away from a designated heat region, via a commercially available IC die layout engine. In one aspect, the designated heat region may be located at a default location and area on the IC die, for example corresponding to a particular heat spreader and/or a particular package.

Upon satisfactory completion of the process 810 providing a thermal management floorplan for the target IC die, a determination is made at 811 of whether or not any IC dies obstruct or impede the thermal path from the optimized IC die to the identified heat sink (e.g., a heat spreader or package substrate). Such IC dies, if any, will be termed “obstructing IC dies.” If the answer to the determination at 811 is NO, thermal coupling elements may be added at process 816, which is described in greater detail later in this disclosure. If the answer to the determination at 811 is YES, a decision or identification occurs at 812 as to whether the obstructing IC dies may be rearranged or re-floorplanned to reduce that obstruction. If the answer to the decision at 812 is “YES”, the obstructing IC die will be re-floorplanned and/or re-arranged (e.g., sized, shaped and/or moved in geographical location) at process 815, such that the thermal path from the designated heat region of the optimized IC die to the identified heat sink is less obstructed. For brevity, this re-floorplanning and/or re-arranging at 815 of the obstructing IC die will be alternately referenced as “clearance re-floorplanning ” The clearance re-floorplanning provides, as will be appreciated, for a less obstructed thermal path for greater heat dissipation. In an aspect, the clearance re-floorplanning at 815 of the obstructing IC dies may provide zero overlap with the designated heat region of the optimized IC die generated at 810. Alternately, the clearance re-floorplanning at 815 of the obstructing IC dies meet a given maximum partial overlap of the designated heat region of the optimized IC die generated at 810. Obstructing IC dies may be arranged as described in any of FIGS. 3A, 3B, 4A, 4B, 5A, 5C, 6A, 6B, or 7.

Referring again to the decision or identification at 812 as to whether the obstructing IC dies may be rearranged or re-floorplanned to reduce that obstruction, the example above assumed an answer of YES. Hypothetically, though, the answer at 812 may be NO. The hypothetical is that certain IC dies may have circuitry such that the clearance re-floorlpanning at 815 cannot both attain the zero or maximum partial overlap floorplan and still maintain desired performance parameters. Accordingly, instead of performing the clearance re-floorplanning at 815, the optimized IC die resulting from 810 may be further optimized by steps of performing another iteration of the process 810, for example, by updating the designated heat region, at 814, and then repeating the decision or identification at 812. Any of these steps, iterations or reiterations may occur by computer simulation or testing.

After successful clearance re-floorplanning at 815, thermal coupling elements may be added at process 816. The thermal coupling element may be added according to any of the various embodiments discussed in reference to FIGS. 4A, 4B, 6A, 6B, 7 and other discussions included in this disclosure. The insertion of thermal coupling elements may be modeled by computer simulation, testing, or any other known methods. In an aspect, the completion of the design 818 can include another computer simulation of the temperature profile and a repeat of the process 800, if necessary.

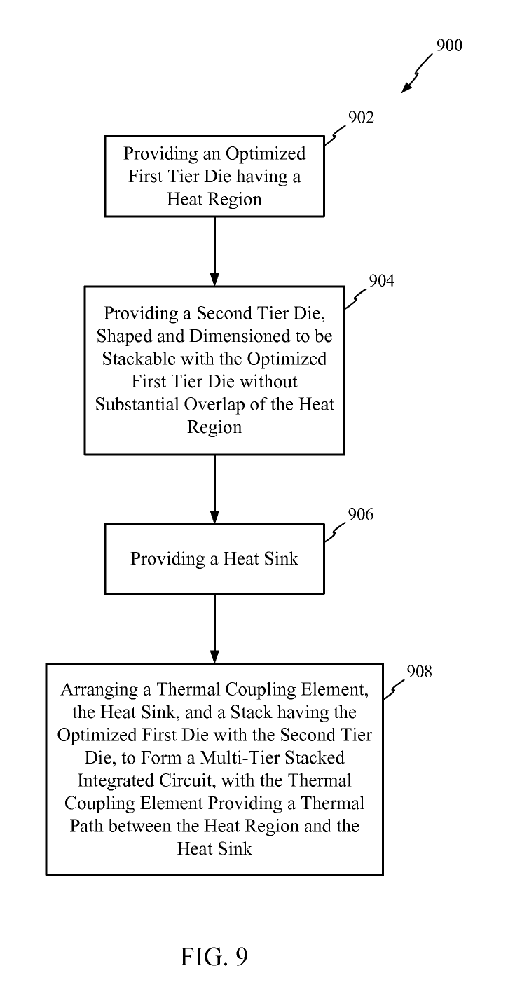

FIG. 9 shows a flow chart diagram of one fabrication 900 of optimized multi-tier IC stack and optimized packages according to methods and processes of one or more exemplary embodiments. Operations further to fabrication 900 can include, according to one or more exemplary embodiments, providing, at 902, an optimized first tier die having a heat region. As previously described, for example in reference to FIG. 3A, in an aspect the optimized first tier die being “optimized” means having a thermal management optimized floorplan. In one further aspect, the thermal management floorplan may include high heat generating circuitry being arranged in the heat region. In another aspect, which may be combined with the previously described aspect, the thermal management floorplan may include sensitive circuitry being arranged moved away from the designated heat region 302_HT.

Continuing to refer to FIG. 9, operations further to fabrication 900 can include providing, at 904, a second tier die floorplanned and/or arranged (i.e., shaped, dimensioned) to be stackable into a multi-tier stack with the first tier die and, when stacked in the multi-tier stack, configured to not substantially overlap the heat region. In an aspect, the 904 feature of the second tier die being “floorplanned and/or arranged to not substantially overlap the heat region” can include the second tier die having zero or substantially zero overlap of the heat region of the first tier. This is illustrated by, for example, referring to FIGS. 3A and 3B, the relation of IC die 304 to the designated heat region 302_HT of the optimized IC die 302. In another aspect, the 904 feature of “floorplanned and/or arranged to not substantially overlap the heat region” can include the second tier die having a non-zero overlap of the heat region of the first tier die. One example of this aspect, referring to FIGS. 5A and 5B, IC die 504 as described in relation to the designated overlapped heat region 502_OVHT of the optimized IC die 502.

Referring still to FIG. 9, operations further to fabrication 900 can also include providing, at 906, a heat sink, and, at 908, arranging a thermal coupling element, the heat sink, and a stack having the first tier die and the second tier die. In an aspect, the arranging includes the thermal coupling element being located to provide a thermal path from the heat region of the first tier die to the heat sink. Examples of providing, at 906, a heat sink include, for example, but are not limited to any one of, or any combination of the FIG. 6A package substrate 610A or heat spreader 630, the FIG. 6B package substrate 610B, the FIG. 7 package substrate 702, the FIG. 6A heat spreader 630 and/or the FIG. 7 heat spreader 750. Examples of providing, at 908, a thermal coupling element, and arranging the thermal coupling element, the heat sink, first tier die and second tier die to form a thermal path between the heat region and the heat sink include, but are not limited to, the FIG. 6A arrangement having thermal coupling element 620A, the FIG. 6B arrangement having thermal coupling element 620B, and/or the FIG. 7 arrangement having thermal coupling elements 720 and 722. As described, the thermal coupling element(s) may be, for example any one or more of a metal, a semiconductor, a thermally conductive plastic, a thermally conductive putty, paste or grease, a thermally conductive tape, a phase change material, and/or a carbon nanotube material.

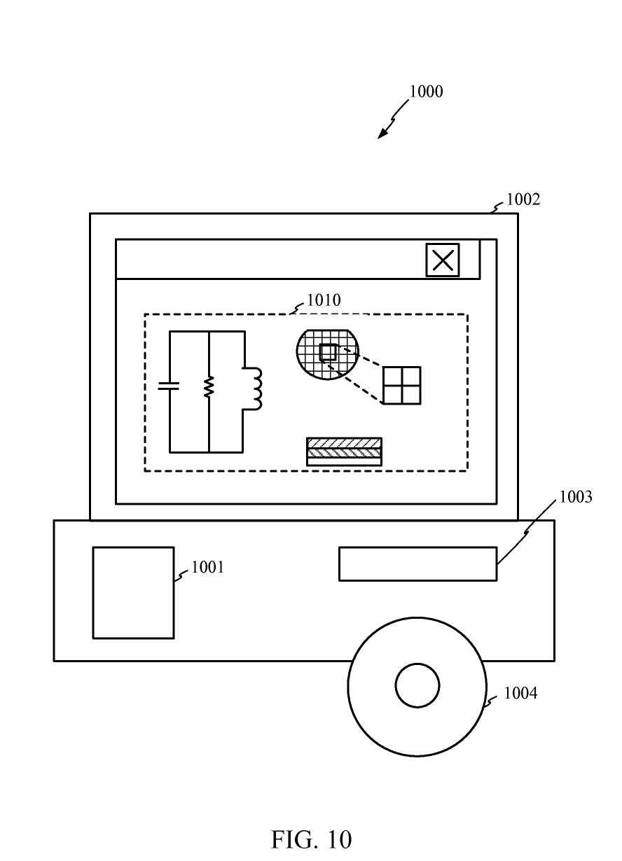

FIG. 10 is a block diagram illustrating a design workstation 1000 that can be used for circuit, layout, logic, wafer, die, and layer design of semiconductor IC dies and packages according to various exemplary embodiments. The design workstation 1000 includes a hard disk 1001 containing operating system software, support files, and design software such as Cadence or OrCAD. The design workstation 1000 also includes a display 1002 to facilitate manufacturing of a semiconductor part 1010 that may include a packaged IC. A storage medium 1004 is provided for tangibly storing the design of the semiconductor part 1010. The design of the semiconductor part 1010 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the semiconductor part 1010 by decreasing the number of processes for manufacturing circuits, semiconductor wafers, semiconductor dies, or layers contained within a packaged IC.

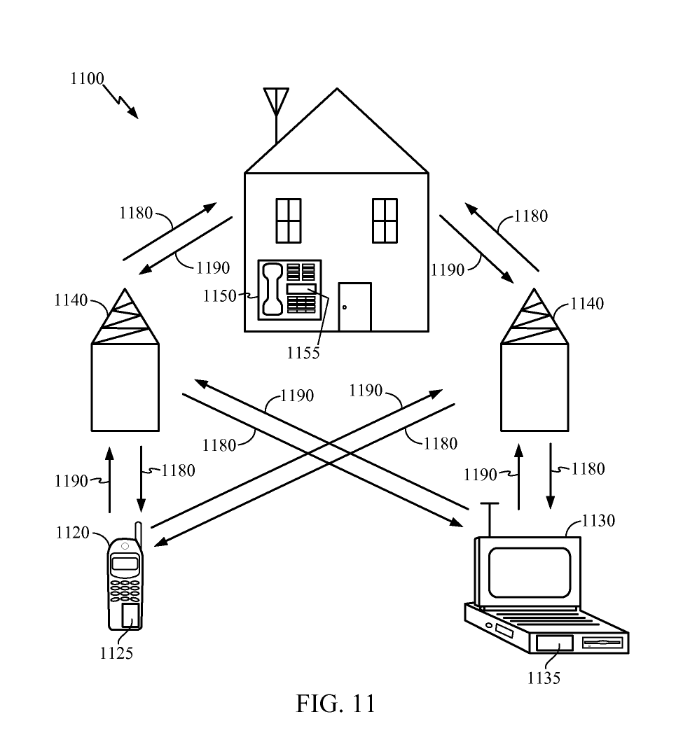

FIG. 11 illustrates an exemplary wireless communication system 1100 in which one or more embodiments of the disclosure may be advantageously employed. For purposes of illustration, FIG. 11 shows three remote units 1120, 1130, and 1150 and two base stations 1140. It will be recognized that conventional wireless communication systems may have many more remote units and base stations. The remote units 1120, 1130, and 1150 include semiconductor devices 1125, 1135 and 1155 (including on-chip voltage regulators, as disclosed herein), which are among embodiments of the disclosure as discussed further below. FIG. 11 shows forward link signals 1180 from the base stations 1140 and the remote units 1120, 1130, and 1150 and reverse link signals 1190 from the remote units 1120, 1130, and 1150 to the base stations 1140.

In FIG. 11, the remote unit 1120 is shown as a mobile telephone, the remote unit 1130 is shown as a portable computer, and the remote unit 1150 is shown as a fixed location remote unit in a wireless local loop system. For example, the remote units may be mobile phones, hand-held personal communication systems (PCS) units, portable data units such as personal data assistants, navigation devices (such as GPS enabled devices), set top boxes, music players, video players, entertainment units, fixed location data units such as meter reading equipment, or any other device that stores or retrieves data or computer instructions, or any combination thereof. Although FIG. 11 illustrates remote units according to the teachings of the disclosure, the disclosure is not limited to these exemplary illustrated units. The disclosed device may be suitably employed in any device that includes a semiconductor device with an on-chip voltage regulator.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method of dissipating heat in a multi-tier stacked integrated circuit, comprising: determining a heat source area or an area in a first tier that is sensitive to heat; re-arranging components in the first tier such that heat sources are located in a designated heat region and circuits sensitive to heat are located away from the designated heat region; adjusting components in the second tier to avoid the heat source area; and providing a thermal coupling element in the second tier, wherein the thermal coupling element is thermally coupled to the heat source area. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of fabricating a multi-tier stacked integrated circuit, comprising:
providing a first tier die having a thermal management floorplan comprising a heat region having an area for a thermal coupling to a heat sink;
providing a second tier die, shaped and dimensioned to be stackable into a multi-tier stack with the first tier die and, when stacked in the multi-tier stack, configured to not substantially overlap the heat region;
providing the heat sink; and
arranging a thermal coupling element, the heat sink, a stack having the first tier die and the second tier die, and the heat sink to form the multi-tier stacked integrated circuit, wherein the thermal coupling element is located to provide a thermal path from the heat region of the first tier die to the heat sink.

2. The method of claim 1, wherein the thermal management floorplan comprises a heat-sensitive component located away from the heat region.

3. The method of claim 1, wherein the first tier die further comprises a heat-source component located in the heat region, the heat-source component designated to be thermally managed by the thermal path from the heat region to the heat sink provided by the thermal coupling element.

4. The method of claim 1, wherein the thermal coupling element includes at least one of:
a metal;
a semiconductor;
a thermally conductive plastic;
a thermally conductive putty, paste or grease;
a thermally conductive tape;
a phase change material; or
a carbon nanotube material.

5. The method of claim 1, wherein the heat sink is a substrate.

6. The method of claim 1, wherein the heat sink is a heat spreader.

7. The method of claim 1, wherein arranging the thermal coupling element, the multi-tier stack of the first tier die and the second tier die, and the heat sink forms the multi-tier stacked integrated circuit with the thermal coupling element contacting a surface of the heat sink and a surface of the heat region.

8. The method of claim 1, providing a second tier die configured to not substantially overlap the heat region, further comprises configuring the second tier die to have no overlap with the heat region.

9. The method of claim 1, further comprising:
providing electrical interconnections between the first tier die and the second tier die, wherein the electrical interconnections are located outside the heat region.

10. A method of dissipating heat in a multi-tier stacked integrated circuit, comprising:
establishing a thermal management floorplan for a first tier die, the thermal management floorplan defining a heat region having an area for thermal coupling to a heat sink, and defining locations within the heat region for heat generating components;
generating a thermal management floorplan for a second tier die, the thermal management floorplan defining a shape and a dimension for the second tier die being stackable with the first tier die without substantial overlap of the heat region; and
determining a thermal coupling element having a shape and a dimension capable of forming, when the first tier die is staked with the second tier die, a thermal path between the heat region of the first tier die and the heat sink.

11. The method of claim 10, wherein generating the thermal management floorplan for the second tier die defines the shape and the dimension for the second tier die that is stackable with the first tier die with no overlap of the heat region.

12. The method of claim 10, further comprising:
providing an initial design for the multi-tiered stacked integrated circuit; and
selecting a target die of the initial design multi-tiered stacked integrated circuit to be the first tier die, wherein the target die has an initial floorplan and wherein generating the thermal management floorplan for the first tier die comprises:
designating a region of the initial floorplan as the heat region, and moving heat sensitive components located within the heat region to locations away from the heat region.

13. The method of claim 10, further comprising:
providing an initial design for the multi-tiered stacked integrated circuit; and
selecting a target die of the initial design multi-tiered stacked integrated circuit to be the first tier die, wherein the target die has an initial floorplan, and wherein generating the thermal management floorplan for the first tier die comprises:
designating a region of the initial floorplan as the heat region; and
moving heat-generating components located outside the heat region to locations within the heat region.

14. The method of claim 13, wherein the initial floorplan of the target die defines one or more heat-sensitive components at locations within the heat region, and wherein generating the thermal management floorplan for the first tier die further comprises moving one or more of the heat-sensitive components to locations away from the heat region.

15. The method of claim 13, further comprising:
identifying a die in the initial design multi-tiered stacked integrated circuit as an obstructing die, the obstructing die having an initial floorplan, and designating the obstructing die to be the second tier die; and
re-floorplanning the second tier die to a clearance floorplan by which the second tier die is stackable with the first tier die with no overlap of the heat region.

16. The method of claim 13, further comprising:
identifying a die in the initial design multi-tiered stacked integrated circuit as an obstructing die, the obstructing die having an initial floorplan, an initial shape and an initial dimension, and designating the obstructing die to be the second tier die; and
re-floorplanning the second tier die to a clearance floorplan by which the second tier die is stackable with the first tier die with no overlap of the heat region.

17. The method of claim 10, further comprising:
determining a heat sink and an arrangement for the heat sink relative to the second tier die stacked with the first tier die, wherein, in the arrangement, the heat sink is able to be thermally coupled to the heat region of the first tier die by the thermal coupling element.

18. The method of claim 17, wherein the heat sink is a heat spreader.

19. The method of claim 17, wherein the heat sink is a substrate.

20. The method of claim 10, wherein the thermal coupling element includes at least one of:
a metal;
a semiconductor;
a thermally conductive plastic;
a thermally conductive putty, paste or grease;
a thermally conductive tape;
a phase change material; or
a carbon nanotube material.

21. The method of claim 10, further comprising:
generating an arrangement of electrical interconnections between the first tier die and the second tier die, wherein said arrangement avoids interconnections in the heat region.

22. The method of claim 21, wherein determining the arrangement of electrical interconnections comprises:
providing a starting arrangement of electrical interconnections between the first tier die and the second tier die, said starting arrangement including interconnections in the heat region; and
moving one or more of the interconnections in the heat region to locations outside the heat region.

23. A multi-tier stacked integrated circuit, comprising:
a first tier die having a heat region;
a second tier die stacked on the first tier die, configured to not substantially overlap the heat region;
a thermal coupling element thermally coupled to a surface area of the heat region; and
a heat sink thermally coupled to the thermal coupling element, wherein the thermal coupling element is configured to form a thermal path from the surface area of the heat region of the first tier die to the heat sink.

24. The multi-tier stacked integrated circuit of claim 23, wherein the thermal coupling element includes at least one of:
a metal;
a semiconductor;
a thermally conductive plastic;
a thermally conductive putty, paste or grease;
a thermally conductive tape;
a phase change material; or
a carbon nanotube material.

25. The multi-tier stacked integrated circuit of claim 23, further comprising:
a substrate, wherein the first tier die is supported on the substrate.

26. The multi-tier stacked integrated circuit of claim 25, wherein the heat sink is a heat spreader above the second tier die.

27. The multi-tier stacked integrated circuit of claim 23, further comprising:
a substrate, wherein the first tier die is supported on the substrate, and wherein the substrate is the heat sink.

28. The multi-tier stacked integrated circuit of claim 23, wherein the heat sink is a heat spreader above the second tier die, multi-tier stacked integrated circuit further comprising:
a substrate;
a lower tier die arranged between the substrate and the first tier die; and
another thermal coupling element, configured to thermally couple another surface area of the heat region to the substrate.
